(19) United States
(12) Patent Application Publication
(10) Pub. No.: US 2009/0194856 A1
(43) Pub. Date: Aug. 6, 2009

(54) MOLDED PACKAGE ASSEMBLY

(76) Inventor: Jocel P. Gomez, Cebu (PH)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/026,952

(22) Filed: Feb. 6, 2008

(51) Int. Cl. H01L 23/495; H01L 21/56

(52) U.S. Cl. 257/675; 257/676; 438/123; 257/E23.04; 257/E21.502

(57) ABSTRACT

A semiconductor die package is disclosed. The semiconductor die package is suitable for mounting on a circuit substrate such as a circuit board. The semiconductor die package comprises a leadframe structure and a semiconductor die coupled to the leadframe structure. A plurality of first conductive structures is attached to the semiconductor die, and a plurality of second conductive structures is attached to the plurality of first conductive structures. The semiconductor die package also comprises a molding material that covers at least portions of plurality of first conductive structures, the leadframe structure, and the semiconductor die.

### CROSS-REFERENCES TO RELATED APPLICATIONS

NOT APPLICABLE

### BACKGROUND

One type of semiconductor die package is a BGA (ball grid array) type of package disclosed in U.S. Patent Publication No. 2005/0051878. The semiconductor die package has a semiconductor die mounted to a carrier. A plurality of solder balls can be attached to the semiconductor die and the carrier. The package can then be flipped over and then mounted to a circuit board or the like.

Although this type of semiconductor die package is useful, improvements can be made. For example, in the semiconductor die package that is specifically illustrated in U.S. Patent Publication No. 2005/0051878, the semiconductor die is open and exposed to contamination. The semiconductor die is exposed to contamination during the semiconductor die mounting process and when an end user uses the semiconductor die package. In some cases, contamination may cause operational problems.

Embodiments of the invention address the above problem and other problems, individually and collectively.

### BRIEF SUMMARY

Embodiments of the invention relate to semiconductor die packages, methods for making semiconductor die packages, and electrical assemblies including semiconductor die packages.

One embodiment of the invention is directed to a semiconductor die package. The semiconductor die package is suitable for mounting on a circuit substrate such as a circuit board. The semiconductor die package comprises a leadframe structure and a semiconductor die coupled to the leadframe structure. A plurality of first conductive structures is attached to the semiconductor die, and a plurality of second conductive structures is attached to the plurality of first conductive structures. The semiconductor die package also comprises a molding material that covers at least portions of the plurality of first conductive structures, the leadframe structure, and the semiconductor die.

Another embodiment of the invention is directed to a method for forming a semiconductor die package. The method comprises molding a molding material around at least a portion of a plurality of first conductive structure precursors, at least a portion of a semiconductor die, and at least a portion of a leadframe structure. The semiconductor die is attached to the leadframe structure, and the first conductive structure precursors are attached to the semiconductor die. Portions of the first conductive structure precursors in the plurality of first conductive structure precursors and the molding material are removed to form a plurality of first conductive structures. A plurality of second conductive structures is attached to the plurality of first conductive structures after molding.

Another embodiment of the invention is directed to a semiconductor die package, where the semiconductor die package suitable for mounting on a circuit substrate such as a circuit board. The semiconductor die package comprises a leadframe structure comprising a die attach pad and a plurality of heat sink structures extending away from the die attach pad, a semiconductor die coupled to the leadframe structure, a plurality of conductive structures attached to the semiconductor die, and a molding material. The molding material covers at least portions of the leadframe structure, and the semiconductor die. The heat sink structures extend in a direction away from the semiconductor die.

Another embodiment of the invention is directed to a method for forming a semiconductor die package. The semiconductor die package is suitable for mounting on a circuit substrate. The method comprises attaching a semiconductor die to a die attach pad of a leadframe structure, where the leadframe structure comprises the die attach pad and a plurality of heat sink structures extending from the die attach pad. The method also includes molding the molding material around at least portions of the leadframe structure, and the semiconductor die.

Other embodiments of the invention are directed to electrical assemblies and methods for forming the same.

### BRIEF DESCRIPTION OF THE DRAWINGS

FIG. 1 is a cross-sectional view of a semiconductor die package according to an embodiment of the invention.

FIG. 2 is a bottom perspective view of the semiconductor die package illustrated in FIG. 1, with a portion of a molding material being partially removed.

FIG. 3 is a bottom perspective view of a leadframe structure.

FIG. 4(a) shows a bottom perspective view of a semiconductor die package embodiment.

FIG. 4(b) shows a top perspective view of the semiconductor die package illustrated in FIG. 4(a).

FIGS. 5(a)-5(i) show package precursors as a semiconductor die package according to an embodiment of the invention is formed.

FIGS. 6-8 are cross-sectional views of other semiconductor die packages according to other embodiments of the invention.

FIG. 9(a) shows a side, cross-sectional view of a semiconductor die package precursor.

FIG. 9(b) shows a side, cross-sectional view of another semiconductor die package according to another embodiment of the invention.

FIGS. 10(a)-10(c) show bottom perspective views of other semiconductor die packages according to embodiments of the invention.

FIG. 11 is a side, cross-sectional view of a semiconductor die package according to another embodiment of the invention.

FIGS. 12(a)-12(b) show cross-sectional views of portions of semiconductor die package embodiments.

FIG. 13 shows a bottom perspective view of another semiconductor die package embodiment, where a portion of a molding material is removed.

FIG. 14 is a bottom perspective view of a leadframe structure according to an embodiment of the invention.

FIG. 15(a) is a bottom perspective view of a semiconductor die package embodiment.

FIGS. 15(b)-15(c) illustrate top perspective views of semiconductor die package embodiments of the invention.

FIGS. 16(a)-16(i) show package precursors as a semiconductor die package according to an embodiment of the invention is formed.

FIG. 17(a) shows a side, cross-sectional view of a semiconductor die package precursor

FIG. 17(b) shows a side, cross-sectional view of a semiconductor die package embodiment.

FIG. 17(c) shows a side, cross-sectional view of a portion of a semiconductor die package precursor.

FIG. 17(d) shows a top perspective view of a portion of a semiconductor die package.

FIGS. 18(a)-18(b) respectively show bottom and top perspective views of semiconductor die package embodiments.

FIGS. 19(a)-19(b) respectively show bottom and top perspective views of semiconductor die package embodiments.

FIGS. 20(a)-20(b) respectively show bottom and top perspective views of semiconductor die package embodiments.

FIG. 21(a) shows a bottom perspective view of another semiconductor die package embodiment.

FIGS. 21(b)-21(e) show different bending options for heat dissipating portions of a leadframe structure.

FIG. 22(a) shows a side, cross-sectional view of a semiconductor die package precursor.

FIG. 22(b) shows a side, cross-sectional view of a semiconductor die package according to an embodiment of the invention.

FIG. 23(a) shows a bottom plan view of a semiconductor die package.

FIG. 23(b) shows a bottom, perspective view of a semiconductor die package, where the package is upside down.

FIG. 23(c) shows a bottom, perspective view of a semiconductor die package embodiment.

FIG. 24(a) shows a bottom plan view of a semiconductor die package.

FIG. 24(b) shows a bottom, perspective view of a semiconductor die package, where the package is upside down.

FIG. 24(c) shows a bottom, perspective view of a semiconductor die package embodiment.

FIG. 25 shows a schematic cross-sectional diagram of a vertical power MOSFET.

In the Figures, like numerals designate like elements and the descriptions of some elements may or may not be repeated.

### DETAILED DESCRIPTION

One embodiment of the invention is directed to a semiconductor die package. The semiconductor die package is suitable for mounting on a circuit substrate such as a circuit board. The semiconductor die package comprises a leadframe structure and a semiconductor die coupled to the leadframe structure. A plurality of first conductive structures is attached to the semiconductor die, and a plurality of second conductive structures is attached to the plurality of first conductive structures. The semiconductor die package also comprises a molding material that covers at least portions of the plurality of first conductive structures, the leadframe structure, and the semiconductor die.

Embodiments of the invention have a number of advantageous features. Such features include new mechanical assembly designs and layouts, including the design of various lead frame structures. In addition, some methods of manufacture can employ over molding, grinding and ball attachment to a solder bumped die or metal (e.g., Cu) stud bumped die that is attached to a leadframe structure. In some cases, the lead frame structure can be bumped, not bumped, and/or can have lead formed terminals that can be connected to a circuit substrate.

The semiconductor die packages according to embodiments of the invention may include one or more semiconductor dies. The one or more semiconductor dies may have the same types of devices or may have different types of devices. Suitable devices may include diode devices, transistor devices and/or driver IC devices. Other examples of suitable devices are described below.

Embodiments of the invention can also be applied to multiple bumped die BGA devices such as the microprocessors, controllers, etc. Embodiments of the invention can also be applied as subparts to other semiconductor devices, where they may be in a stacked, molded BGA (ball grid array) type assembly, or molded together with other devices in an SIP (system in a package) assembly.

Embodiments of the invention provide for a number of advantages. Embodiments of the invention may have some, or all of such advantages. For example, some of the embodiments incorporate power transistors. Such embodiments can have low RDS (source-drain resistance), when compared to packages that use standard wire bonding and clip bonding.

Also, it has been a challenge to mold a bumped die that is already attached to a leadframe substrate in a standard BGA or folded BGA type of package. Embodiments of the invention can use a unique molding, grinding and ball attach method to form a semiconductor die package with molded bumped dies.

Embodiments of the invention may also be used with copper stud bumps, and embodiments of the invention can be robust. Compared to an existing, standard BGA and FLF BGA type package, embodiments of the invention are more reliable, durable, and robust. This is because the semiconductor die is protected with an epoxy mold compound in some embodiments of the invention. The resulting semiconductor die package can operate in a rigid environment where existing standard BGA and FLF BGA packages cannot work for a long period of time.

Embodiments of the invention can also be sized so that they are near chip scale packages. Embodiments of the invention can use a small leadframe structure and a thicker molding. Embodiments of the invention can also be used in products that need denser and more compact device integration on a PCB or other type of circuit substrate.

Some embodiments of the invention also provide various molding and lead forming options and heat sink options, which also provide end user application benefits.

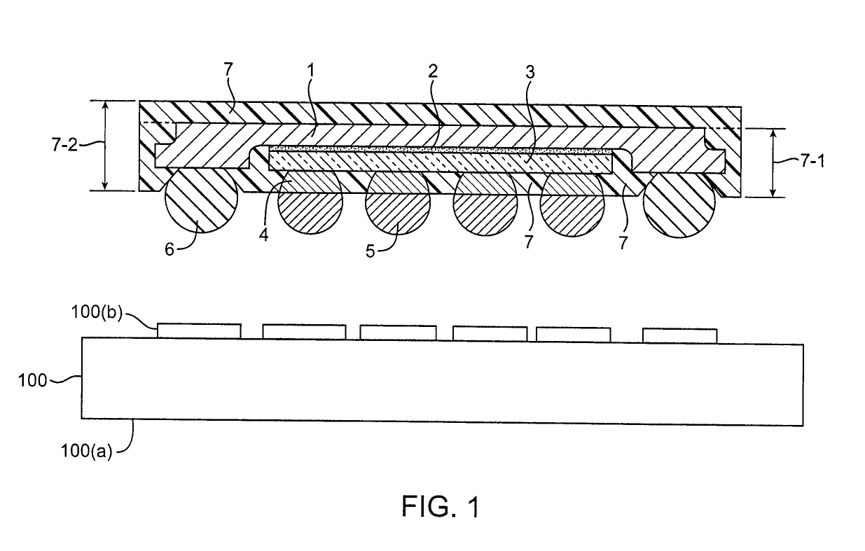

FIG. 1 shows a semiconductor die package according to an embodiment of the invention. The semiconductor die package is a BGA (ball grid array) type package and is suitable for mounting on a circuit substrate 100, and can thereafter form an electrical assembly. In this example, the illustration of the circuit substrate 100 is simplified for clarity of illustration. It includes an insulating layer 100(a) and a discontinuous pattern of metal 100(b) on the insulating layer 100(a). The circuit substrate 100 may take other forms in other embodiments of the invention, and could include many more insulating layers and metal layers.

The illustrated semiconductor die package comprises a leadframe structure 1 and a semiconductor die 3 coupled to a die attach pad in the leadframe structure 1 using a conductive adhesive 2 such as a conductive epoxy or solder. Third conductive structures 6 are attached to leads in the leadframe structure 1. The leads are disposed around the semiconductor die 3.

The semiconductor die 3 may comprise a MOSFET, but may comprise any suitable semiconductor device in other embodiments of the invention. Suitable devices may include vertical or horizontal devices. Vertical devices have at least an input at one side of the die and an output at the other side of the die so that current can flow vertically through the die. Horizontal devices include at least one input at one side of the die and at least one output at the same side of the die so that current flows horizontally through the die.

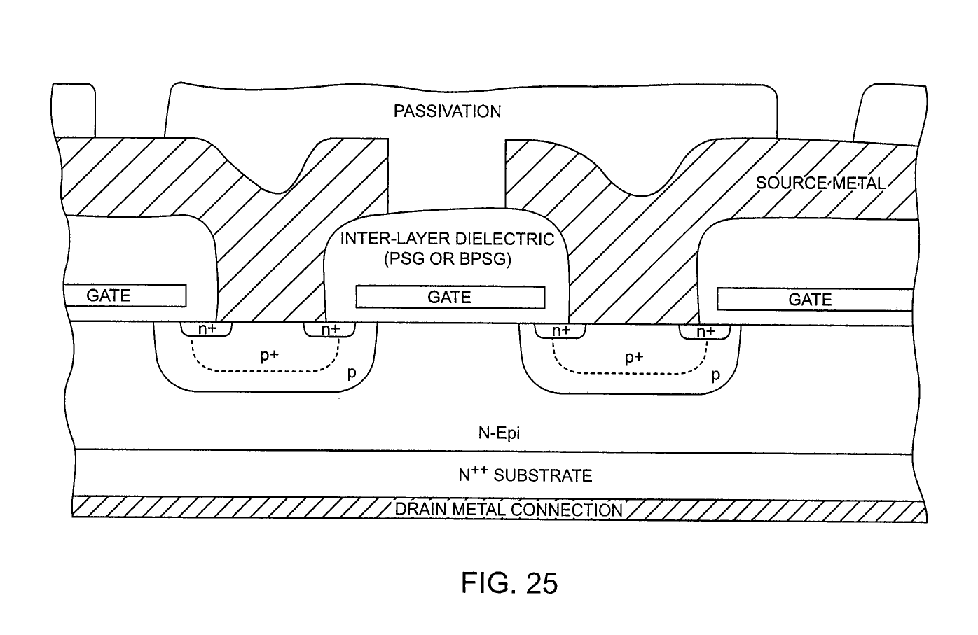

Vertical power transistors include VDMOS transistors and vertical bipolar transistors. A VDMOS transistor is a MOSFET that has two or more semiconductor regions formed by diffusion. It has a source region, a drain region, and a gate. The device is vertical in that the source region and the drain region are at opposite surfaces of the semiconductor die. The gate may be a trenched gate structure or a planar gate structure, and is formed at the same surface as the source region. Trenched gate structures are preferred, since trenched gate structures are narrower and occupy less space than planar gate structures. During operation, the current flow from the source region to the drain region in a VDMOS device is substantially perpendicular to the die surfaces. An example of a vertical MOSFET is shown in FIG. 25. While P— or N-channel MOSFETs can be used in embodiments of the invention, N-channel MOSFETs are preferred.

Referring again to FIG. 1, the lead frame structure 1 may comprise a conductive material such as copper or a copper alloy and may be manufactured through etching, stamping, or any other suitable process. It may also be fully or selectively plated with a metal such as NiPdAu, Ag, Ni, or any other suitable material. The selected plating chemistry can be capable of providing better adhesion to the molding material 7, conductive adhesive 2, or third conductive structure 6.

The semiconductor die package can also include a number of conductive structures to allow the semiconductor die package to communicate with the circuit substrate 100. For example, as illustrated in FIG. 1, a plurality of first conductive structures 4 is attached to the semiconductor die 3, and a plurality of second conductive structures 5 is attached to the plurality of first conductive structures 4. Interfaces can be respectively formed between the pairs of the first conductive structures 4 and second conductive structures 5. The interfaces between the pairs of first conductive structures 4, and the second conductive structures 5, may form a line or may be substantially coplanar with the exterior surface of the molding material 7. The first and second conductive structures 4, 5 can form gate and source terminals for a MOSFET in the semiconductor die 3.

A plurality of third conductive structures 6 may be disposed around the semiconductor die 3, and may electrically and mechanically connect to the leadframe structure 1. As shown, the third conductive structures 6 have heights that are greater than the heights of each of the first and second conductive structures 4, 5. The third conductive structures 6 can serve as drain terminals for one or more drain regions in the semiconductor die 3.

The first, second, and third conductive structures 4, 5, 6 may be formed of any suitable conductive material. Suitable materials include conductive transition metals such as copper and aluminum. Such materials may also be in the form of stud bumps, which may be formed using a traditional wirebonding process. In some embodiments, at least one of the first, second, and third conductive structures 4, 5, 6 may be formed of solder. Solder bumps 30 can be formed using various processes and/or materials including electroless nickel-gold, solder screen printing, pick and place, etc.

Further, in some embodiments, the first conductive structures 4 can have a higher melting point than the second and/or third conductive structures 5, 6. As will be explained in detail below, the first conductive structures 4 may first be molded with the molding material 7. After molding, the second and third conductive structures 5, 6 may be deposited on the first conductive structures 4 and the leads of the leadframe structure 1. The second and third conductive structures 5, 6 may be reflowed without reflowing the first conductive structures 4.

The semiconductor die package also comprises a molding material 7 that covers at least portions of the plurality of first conductive structures 4, the leadframe structure 1, and the semiconductor die 3. As shown, the molding material 7 surrounds the sides of the first conductive structures 4, but does not surround the sides of the second conductive structures 5. The molding material 7 also completely surrounds the semiconductor die 3 and the leadframe structure 1 in this embodiment. As shown in FIG. 1, the molding material 7 may be molded over the top surface of the leadframe structure 1 and may have a height that is illustrated by reference number 7-2.

In other embodiments, as shown by reference numeral 7-1, it is possible to have a molding material 7 that has an exterior surface that is substantially coplanar with an exterior surface of the leadframe structure 1, to expose the exterior surface of the leadframe structure 1 through the molding material 7. In this case, the molding material 7 would have a thickness that is substantially equal to the die attach pad of the leadframe structure 1, the conductive adhesive 2, the semiconductor die 3, and the first conductive structures 4. When the top surface of the leadframe structure 1 is exposed, heat can more readily dissipate from the semiconductor die 3.

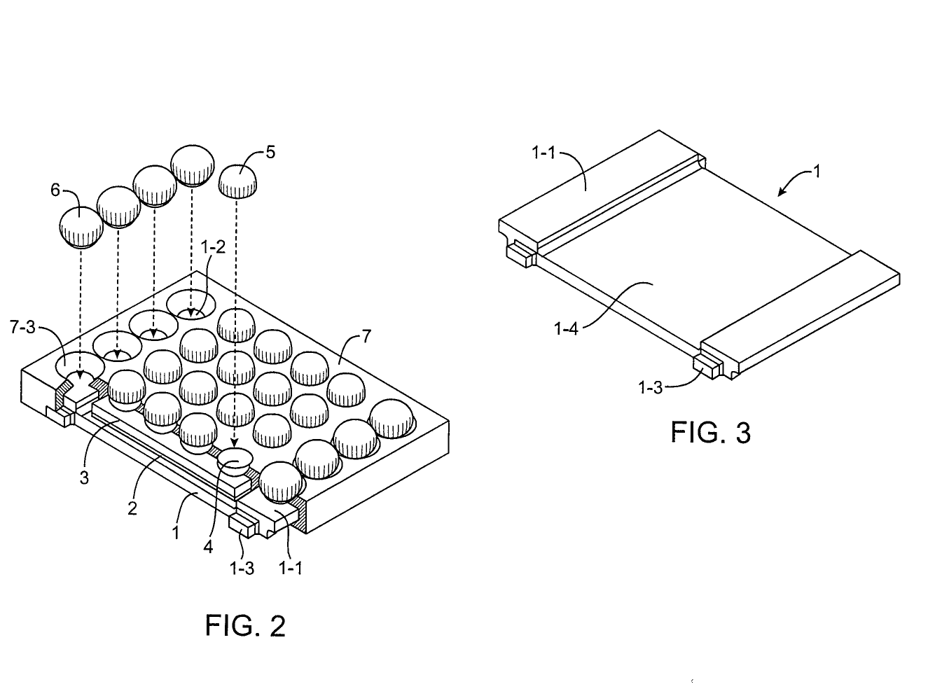

FIG. 2 shows a bottom perspective view of the semiconductor die package illustrated in FIG. 1. A portion of the molding material 7 is removed to better show other features of the semiconductor die package. As shown by reference number 1-2, surfaces of the leadframe structure 1 can be exposed through circular apertures in the molding material 7. Also, the apertures in the molding material 7 may have angled aperture walls 7-3 so that the apertures can easily receive the third conductive structures 6.

Referring to both FIGS. 2 and 3, the leadframe structure 1 comprises two frame bump supports 1-1 (which may also be characterized as drain leads in this example). Frame tie bars 1-3 extend from the frame bump supports 1-1. The frame tie bars 1-3 may join the leadframe structure 1 to other leadframe structures in an array of leadframe structures. As shown in FIG. 3, there are two frame bump supports on opposite sides of a die attach pad 1-4. In other embodiments, there could be one, three, or four distinct frame bump support sections in the leadframe structure 1.

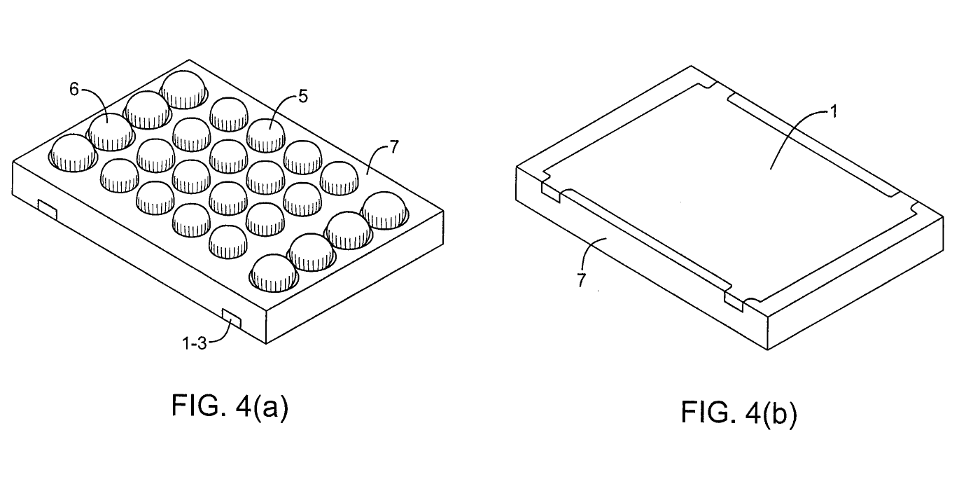

FIG. 4(a) shows a bottom perspective view of the semiconductor die package shown in FIG. 1, while FIG. 4B shows a top perspective view of a semiconductor die package embodiment. As shown in FIG. 4(b), an exterior surface of the leadframe structure 1 may be substantially coplanar with an exterior surface of the molding material 7. If desired, an additional heat sink (not shown) could be attached to the semiconductor die package shown in FIG. 4(b) to improve the heat dissipation properties of the semiconductor die package. The top surface of the leadframe structure 1 is not overmolded with the molding material 7 as in the embodiment that is specifically illustrated in FIG. 1.

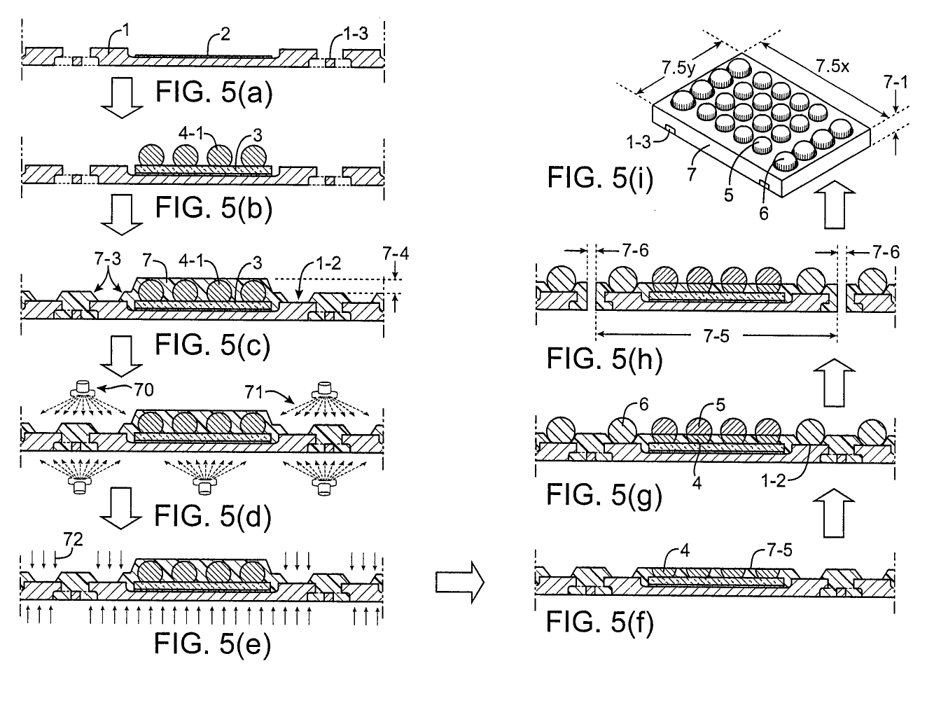

Other embodiments of the invention are directed to methods for making the above-described semiconductor die packages. One embodiment of the invention is directed to a method comprising attaching a semiconductor die to a leadframe structure, forming a plurality of first conductive structure precursors on the semiconductor die, forming a plurality of first conductive structures from the plurality of first conductive structure precursors, and attaching a plurality of second conductive structures to the plurality of first conductive structures. Methods according to embodiments of the invention can be described with reference to FIGS. 5(a)-5(f).

Referring to FIG. 5(a), a conductive adhesive 2 is deposited on a flat die attach pad of the leadframe structure 1. In some embodiments, the conductive adhesive 2 is a conductive, die attach epoxy material. The conductive adhesive 2 may comprise a Pb or Pb-free material. Its reflow curing temperature may be lower than the reflow curing temperature of first conductive structures precursors 4-1 on the semiconductor die 3, if the semiconductor die 3 is first bumped with solder bumps or the like.

FIG. 5(b) shows a die attach process. The semiconductor die 3 may comprise a transistor or MOSFET device, and may or may not include the first conductive structure precursors 4-1 on it as it is attached to the conductive adhesive 2. The one or more first conductive structure precursors 4-1 (e.g., solder bumps) may eventually form gate and/or source connections to gate and source regions at a front surface of the MOSFET device in the semiconductor die 3. The back surface of the semiconductor die 3 may be coupled to the leadframe structure 1, and it may serve as the drain terminal for the MOSFET.

In the illustrated embodiment, the first conductive structure precursors 4-1 can first be attached to the semiconductor die 3, and then the resulting combination may be mounted to the leadframe structure 1. In other embodiments, the semiconductor die 3 may first be mounted to the leadframe structure 1. Then, the first conductive structure precursors 4-1 could be attached to the semiconductor die 3.

FIG. 5(c) shows a molding material 7 being formed around the first conductive structure precursors 4, the semiconductor die 3, and part of the leadframe structure 1. Any suitable molding tool may be used to mold the molding material 7. In some embodiments, the cavities of the molding tool may have angled dimple designs (not shown) to form angled aperture walls 7-3. The formed apertures may expose contact regions 1-2 of the leadframe structure 1. The previously described third conductive structures can be deposited in the apertures in the molding material 7 and on the contact pads 1-2. Reference number 7-4 shows an over mold height of the molding material 7 on the first conductive structures 4-1. The surfaces of the first conductive structure precursors 4-1 are fully molded and need not touch the surfaces forming the mold tool cavities.

FIG. 5(d) shows a de-flashing process. A de-flashing process can remove any mold flashes that may appear on the metal surface by the use of conventional pressurized water 71 from water jet nozzle 70. De-flashing may alternatively be performed using a laser beam or a laser in combination with a water jet.

FIG. 5(e) shows a plating process. This process may applicable when the material of the lead frame structure 1 that is used is bare copper. Plating is to be applied on all exposed metal as represented by plating direction 72. The plating chemistry may be chosen to provide reliable adhesion to the third conductive structures 6 (e.g., third solder balls), or to provide reliable protection from corrosion.

FIG. 5(f) shows a surface grinding process, which is an example of a material removal process. Surface grinding can occur using a grinding wheel, a CMP (chemical mechanical polishing process, or the like. The surface grinding process removes a portion (e.g., about half) of the first conductive structure precursors 4-1 along with an appropriate amount of molding material 7 (represented by molding height 7-4) in order to expose the internal surfaces of the first conductive structures precursors 4-1 and to form the first conductive structures 4. The resulting first conductive structures 4 can have surfaces which, along with an exterior surface of the molding material 7, can form a flat surface 7-5.

FIG. 5(g) shows a process for attaching the second and third conductive structures 5, 6 to the precursor structure shown in FIG. 5(f). The second conductive structures 5 may be attached to the processed first conductive structures 4. Any suitable process including pick and place, screen printing, etc. may be used to deposit and attach the second conductive structures 5 to the first conductive structures 4.

Before, after, or during the deposition of the second conductive structures 5 on the precursor structure shown in FIG. 5(f), the third conductive structures 6 can be deposited on the exposed regions 1-2 (which may be plated or unplated) of the leadframe structure 1. In preferred embodiments, the second and third conductive structures 5, 6 are deposited on the precursor structure in FIG. 5(f) during the same processing step. After they are attached to the precursor structure in FIG. 5(f), the second and third conductive structures 5, 6 may be subjected to a reflow process to establish connections between the first and second conductive structures 4, 5, and the third conductive structures 6 and the leadframe structure 1. The first, second, and third conductive structures 4, 5, 6, may contain Pb or Pb free materials.

FIG. 5(h) shows a singulation process. Singulation can be performed using a sawing process. A sawing width is represented by dimensions 7-6 in order to come-up with singulated units, each of which is represented by dimension 7-5. Singulation may alternatively be performed using a trimming process when the molding of the lead frame structure is performed on each unit individually.

FIG. 5(i) shows a singulated package. After singulation, it is subjected to electrical testing, device marking, and then tape and reel.

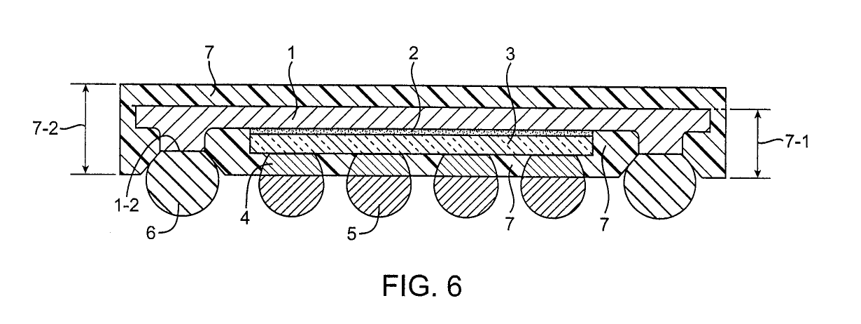

FIG. 6 shows a side, cross-sectional view of a semiconductor die package according to another embodiment of the invention. The semiconductor die package in FIG. 6 is similar to the package shown in FIG. 1. The main difference is that the leadframe structure contact pad 1-2 is designed so that it is cylindrically shaped through a partial (e.g., half) etching process. Also, the molding layout around the contact pad 1-2 is flat. Also, there is no angled aperture wall 7-3 (as shown in FIG. 2) in the embodiment illustrated in FIG. 6. Compared to the semiconductor die package embodiment in FIG. 1, this semiconductor die package embodiment is easier to mold. Although the top surface of the leadframe structure 1 is overmolded with a molding material 7 in this embodiment, in other embodiments, the top surface of the leadframe structure 1 could be exposed.

The process flow for producing the semiconductor die package illustrated in FIG. 6 can be the same as described above with respect to FIGS. 5(a)-5(h), except that the molding process would be modified to not produce the angled wall 7-3 and the exposed frame contact pad 1-2.

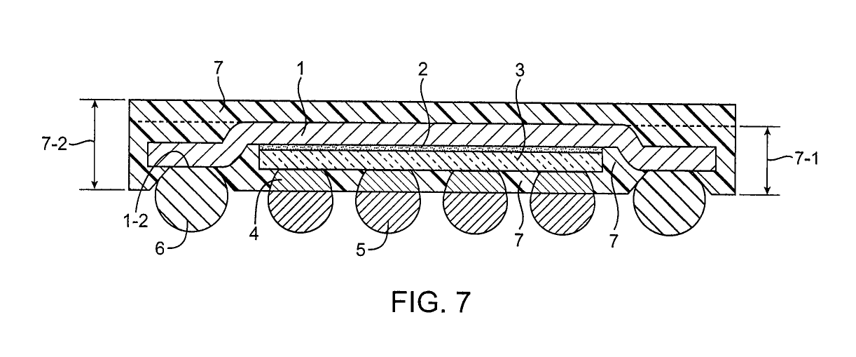

FIG. 7 shows a side, cross-sectional view of another semiconductor die package embodiment. The main difference between this embodiment as compared to the embodiment in FIG. 1 is that the lead frame structure 1 is designed so that it is of a single gauge thickness. Contact pad 1-2 is obtained through a down set or downward bending process.

The process flow for producing the semiconductor die package embodiment can be the same as in FIGS. 5(a)-5(h). This package embodiment can use the mold design specifically described in FIGS. 5(a)-5(h), since an angled aperture wall 7-3 is illustrated. The lead frame structure manufacturing cost may be less than the cost as compared to the semiconductor die package embodiment in FIGS. 5(a)-5(h). This semiconductor die package embodiment can expose the back surface 7-1 of the leadframe structure, or the back surface 7-1 could specifically be over molded as illustrated in FIG. 7.

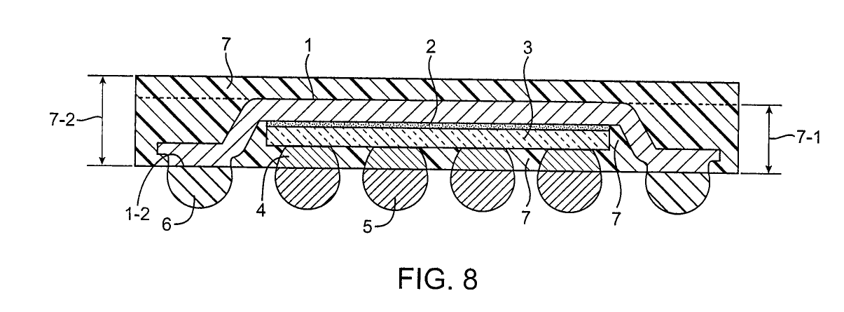

FIG. 8 shows another semiconductor die package embodiment of the invention. This embodiment combines features of the semiconductor die packages illustrated in FIGS. 6 and 7.

The method of manufacturing the semiconductor die package embodiment in FIG. 8 is the same as described above, with respect to FIGS. 5(a)-5(h), except that the molding process may not form an angled aperture wall 7-3.

The embodiment illustrated in FIG. 8 can be ideal for solder screen printing as an alternative to solder ball attachment, because a flat surface is formed after the grinding process. The dispensed second and third conductive structures 5, 6 will be self-formed as solder balls, when they are subjected to an appropriate thermal reflow temperature.

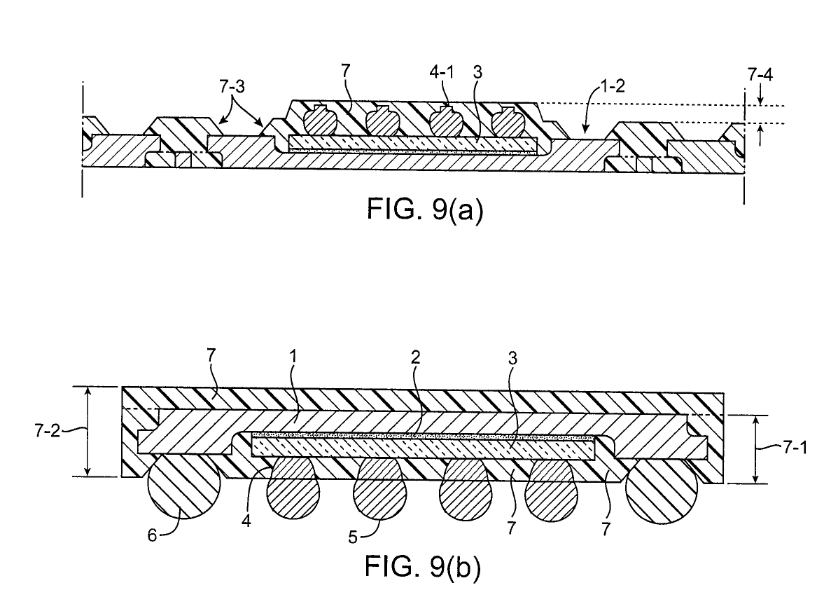

FIG. 9(a) shows another semiconductor die package precursor embodiment. FIG. 9(a) shows first conductive structure precursors 4-1 in the form of copper stud bumps, as an alternative to solder bumps. Metal stud bumping may be done at wafer level or may be done after the semiconductor die is attached to the leadframe structure 1. Examples of copper stud bumping processes are described in U.S. Pat. Nos. 6,731,003, and 7,271,497, which are herein incorporated by reference in their entirety for all purposes.

As in prior embodiments, this design option can also undergo an over molding process 7-4. Over molding 7-4 can be removed during the previously described grinding process. During the grinding process, half of the first conductive structure precursors 4-1 can be removed and surfaces of the formed first conductive structures 4 can remain and can be exposed through the molding material 7. Then, a plating process can be performed, if desired. After further processing (as described above in other embodiments), the semiconductor die package illustrated in FIG. 9(b) can be formed. The resulting semiconductor die package illustrated in FIG. 9(b) can cost less than packages that use solder bumps.

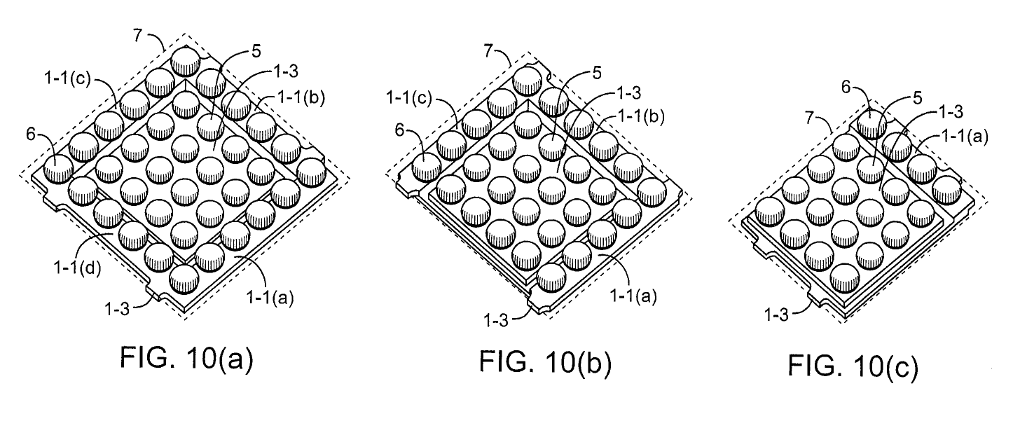

FIG. 10(a) shows a bottom perspective view of a semiconductor die package including a leadframe structure 1 with a four sided drain bump support. The drain side bump supports 1-1(a), 1-1(b), 1-1(c), 1-1(d) can have third conductive structures (e.g., solder bumps) deposited thereon. This embodiment includes a semiconductor die surrounded on four sides with third conductive structures 6 in the form of drain bumps. The lead frame structure 1 has a rectangular slot in the center which receives the semiconductor die 3. This semiconductor die package embodiment is in the form of a molded BGA or ball grid array. The dashed line 7 represents a molded package outline illustrating the maximum length and width of the package.

FIG. 10(b) shows a leadframe structure comprising a three sided drain bump support 1-1(a), 1-1(b), 1-1(c). Third conductive structures 6 in the form of drain bumps are arranged in “U” shape in this embodiment. One side is free from drain bumps so that when the semiconductor die package is used in a particular application, it will serve as a copper trace routing area that connects to gate and source bumps. The illustrated semiconductor die package is a molded BGA package and the dashed line 7 represents a maximum molded package outline for length and width.

FIG. 10(c) shows another semiconductor die package embodiment. In this embodiment, the semiconductor die package comprises a one sided drain bump support 1-1(a). The semiconductor die package is a molded BGA type package and the dashed line 7 represents a maximum width and length for a molded package outline.

Any of the packages illustrated in FIGS. 1-9 can be used with the configurations in FIGS. 10(a)-10(c).

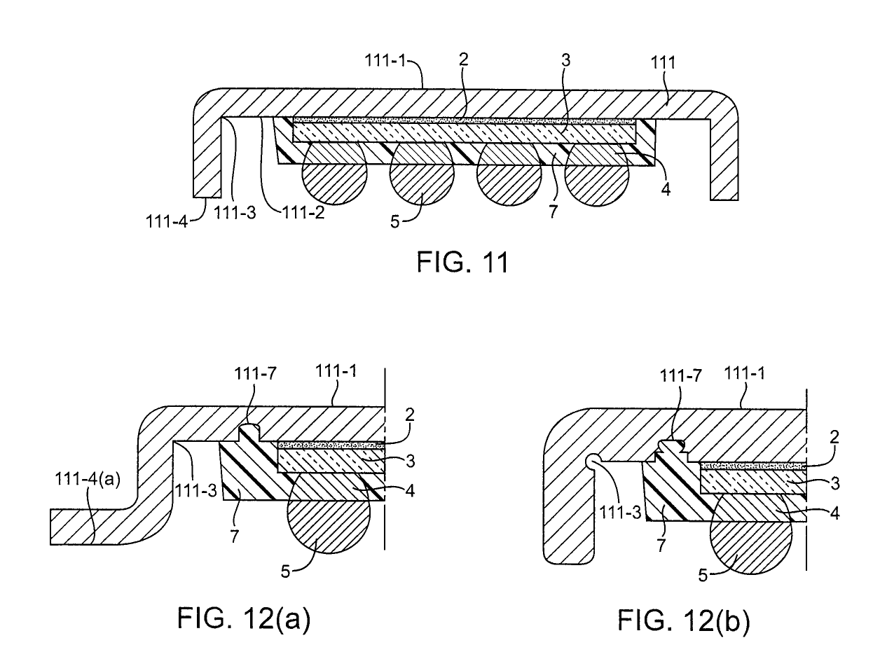

FIG. 11 shows another semiconductor die package according to another embodiment of the invention. The semiconductor die package is a BGA (ball grid array) type package as in FIG. 1. The semiconductor die package comprises a leadframe structure 111 and a semiconductor die 3 coupled to a die attach pad in the leadframe structure 111 using a conductive adhesive 2 such as a conductive epoxy or solder. The leadframe structure 111 comprises leads 111-4 that surround the semiconductor die 3. The leads 111-4 may be defined by bent corners 111-3. The leadframe structure 111 may also include a die attach pad 111-2 that is oriented substantially perpendicular to the leads 111-4, as well as a lead frame flat top surface 111-1 on an opposite side of the leadframe structure 111 as the die attach pad 111-2.

The lead frame structure 111 may comprise copper or a copper alloy and may be manufactured through etching, stamping, or any other suitable process. The lead frame structure 111 material may comprise bare copper. It may also be fully or selectively plated with a metal such as NiPdAu, Ag, Ni, or any other suitable material. The selected plating chemistry can be capable of providing better adhesion to the molding material 7, or conductive adhesive 2.

As in the prior embodiments, the semiconductor die package can also include a number of conductive structures to allow the semiconductor die package to communicate with a circuit substrate (not shown). For example, as illustrated in FIG. 11, a plurality of first conductive structures 4 is attached to the semiconductor die 3, and a plurality of second conductive structures 5 is attached to the plurality of first conductive structures 4. Interfaces can be respectively formed between the pairs of first conductive structures 4 and second conductive structures 5. The interfaces between the pairs of first conductive structures 4, and the second conductive structure 5, may form a line or may be substantially coplanar with the exterior surface of the molding material 7.

Unlike the embodiment shown in FIG. 1, the semiconductor die package could have, but need not have, a plurality of third conductive structures that may electrically and mechanically connect to the leadframe structure 7. Instead of the previously described third conductive structures, the leads 111-4 of the leadframe 111 that surround the semiconductor die 3 may route output current from the back surface of the semiconductor die 3 to an underlying board. As shown, the leads 111-4 have heights that are greater than the heights of each the stacked first and second conductive structures 4, 5.

The semiconductor die package also comprises a molding material 7 that covers at least portions of the plurality of first conductive structures 4, the leadframe structure 1, and the semiconductor die 3. As shown, the molding material 7 surrounds the sides of the first conductive structures 4, but does not surround the sides of the second conductive structures 5. The molding material 7 also completely surrounds the semiconductor die 3 and is spaced inward from the leads 111-4.

FIG. 12(a) shows a close up view of another portion of another semiconductor die package embodiment, with a configuration that is similar to the one shown in FIG. 11. The leadframe structure 111 in FIG. 12(a) may have a U-groove 111-7 on four sides near an edge region of the molding material 7. The main purpose of the U-groove is to help the molding material 7 lock onto the lead frame structure surface 111-2. It also helps to prevent any moisture intrusion from the exterior of the semiconductor die package to the semiconductor die 3 by providing a longer path to the semiconductor die 3. The formed terminal lead 111-4(a) may be also provide stronger and larger solder joints. The bent corner 111-3 may be a sharp corner or may have an internal bending ratio that may reduce the possibility of corner cracks.

FIG. 12(b) shows a close up view of another portion of another semiconductor die package embodiment, with a configuration that is similar to the one shown in FIG. 1. In FIG. 12(b), there may be a small “U” groove on the bent corner 111-3. One purpose of this U-groove is to help guide the lead bending process. Also, an improved mold locking groove 111-7 design may also be an option to provide strong mold locking. As illustrated, the mold locking groove 111-7 includes a two-step structure.

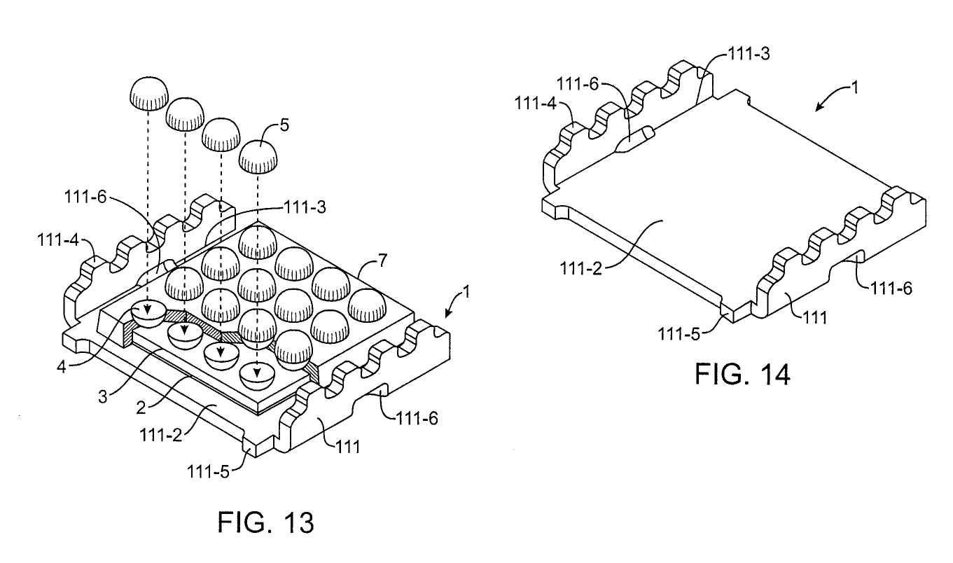

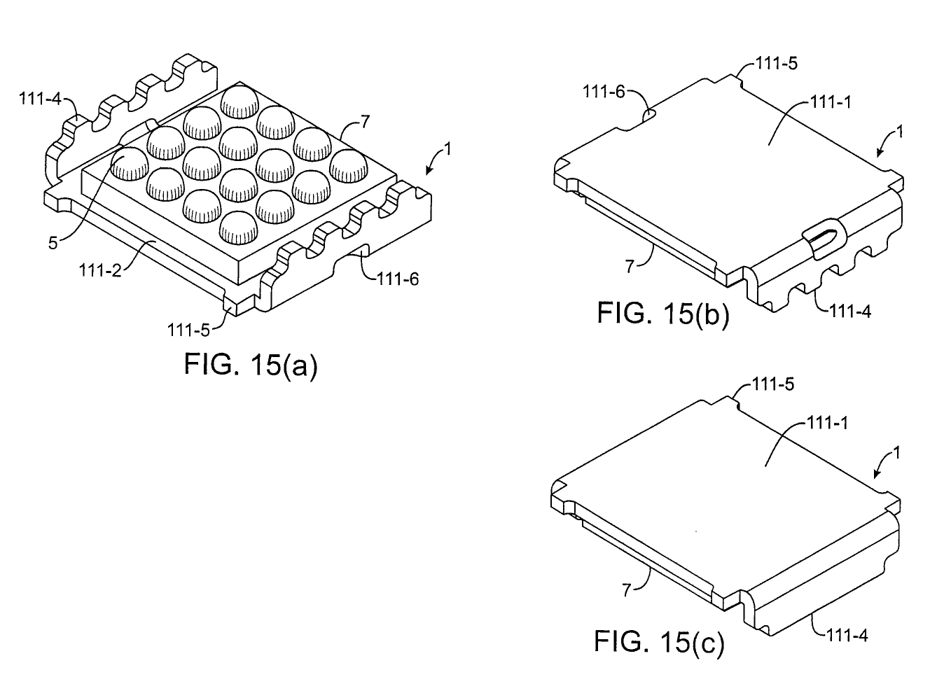

FIG. 13 shows a bottom, perspective view of a semiconductor die package embodiment, with part of the molding material being removed. FIG. 14 shows a bottom, perspective view of a leadframe structure 111 according to an embodiment of the invention. FIG. 15 shows a bottom, perspective view of a semiconductor die package embodiment. FIG. 15(b) shows a top perspective view of the leadframe structure 111.

In FIGS. 13-15(b), the leadframe structure 111 comprises a corner slot 111-6, attach tip structures 111-4 (for attaching the leadframe structure 111 to an underlying circuit substrate) extending from vertically oriented leads, a bent corner slot 111-3 between the leads and a die attach pad 111-2, and tie bars 111-5 extending from the die attach pad 111-2.

FIG. 15(c) shows another leadframe structure 111 embodiment. This embodiment does not have a slot on an edge of a bent corner. Also, the lead edges that are flat (as opposed to having stud tips as in the embodiment shown in FIG. 15(b)).

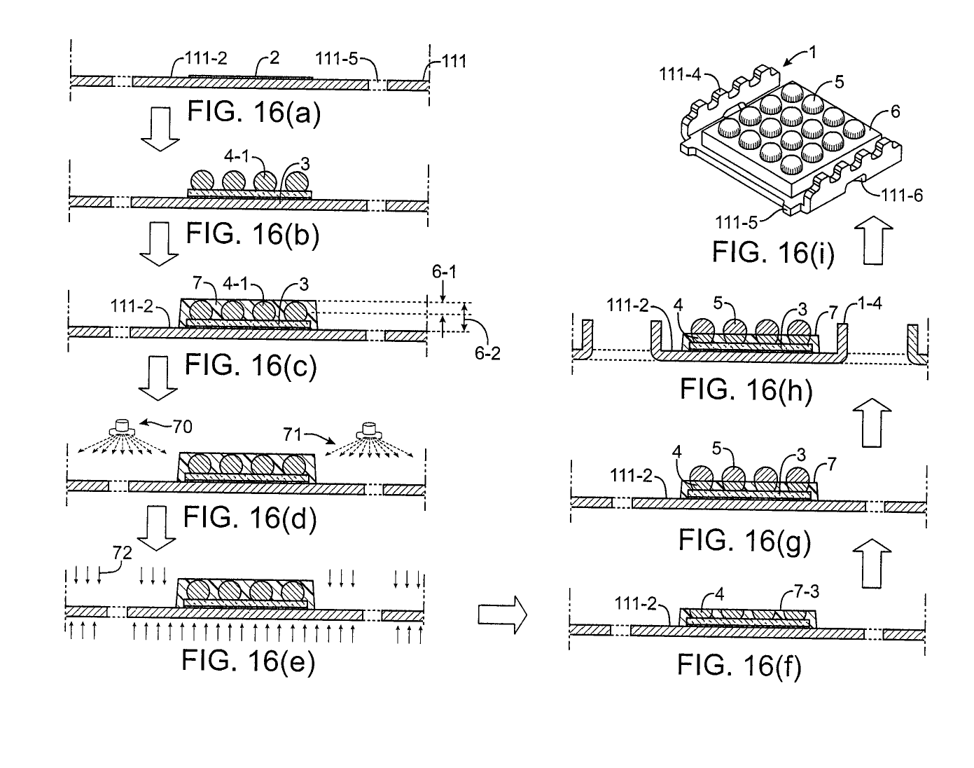

Methods for forming semiconductor die packages of the type shown in FIGS. 11-15(c) are shown in FIGS. 16(a)-16(i).

FIG. 16(a) shows a conductive adhesive 2 such as a die attach epoxy being deposited on the flat die attach pad 111-2 as a first step in the method. The conductive adhesive 2 may comprise a Pb or Pb free material, and its reflow curing temp can be lower that the first conductive structures 4 (e.g., solder bumps).

FIG. 16(b) shows a die attach process for a semiconductor die 3 that has first conductive structure precursors 4-1 on it. The semiconductor die 3 is attached to the leadframe structure 111 via the conductive adhesive 2. The first conductive structure precursors 4-1 may be present on the semiconductor die 3, before it is attached to the leadframe structure 111 or after it is attached to the leadframe structure 111. The semiconductor die 4 may comprise a transistor or MOSFET device, which may use one or two first conductive structures as gate terminals. Any remaining first conductive structures can serve as source terminals. The back side of the semiconductor die 3 can serve as a drain contact area. The size and thickness of semiconductor die 3 can vary, and the quantity and arrangement of conductive structures can also vary in embodiments of the invention.

FIG. 16(c) shows a molding process for an attached bumped die 3. The over molding height (illustrated by reference number 6-1) on the first conductive structures precursors 4-1 allows them to be fully molded. The top surfaces of the first conductive structures 4 do not touch the mold tool cavities.

FIG. 16(d) shows a de-flashing process. This will remove any mold flashes that may appear in metal surface by the use of conventional pressurized water 71 from water jet nozzles 70. De-flashing may alternatively be performed using laser beams or the laser aided de-flashing.

FIG. 16(e) shows the plating process. This plating process may applicable when the lead frame structure material that is used is bare copper. The plating that is to be applied on all exposed metal surfaces is represented by plating direction 72. The plating chemistry may be in any form that may provide reliable solder joints to the leadframe structure, and that may provide reliable protection from corrosion.

FIG. 16(f) shows the surface grinding of molded frames. In this process step, portions of the first conductive structure precursors 4-1 and the molding material 6 are removed (for example using a grinding process), to form first conductive structures 4. The resulting surface that remains can be represented by a flat surface 7-3.

FIG. 16(g) shows an attachment process for the second conductive structures 5. The second conductive structures 5 are attached to the exposed first conductive structures 4. After the second conductive structures 5 are attached (e.g., using deposition processes) to the first conductive structures 5, a reflow process can be performed to establish a connection between the second conductive structures 5 and the first conductive structures 4. If the first and/or the second conductive structures 4, 5 are solder balls, they may contain Pb or Pb free materials.

FIG. 16(h) shows a lead formation and singulation process. This process can be performed mechanically using a punch and die.

FIG. 16(i) shows a singulated unit that is subjected to electrical testing, device marking, and then tape and reel.

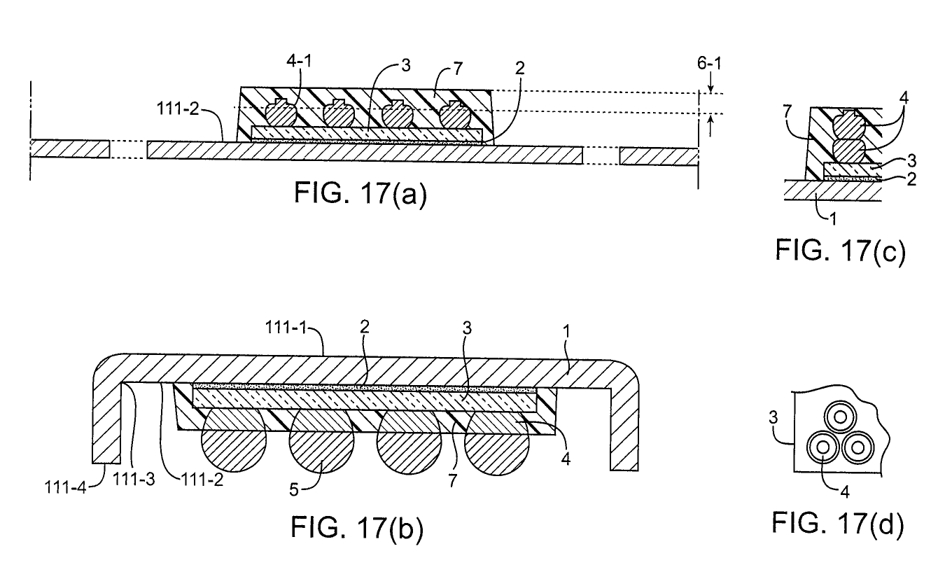

FIG. 17(a) shows first conductive structure precursors 4-1 in the form of copper stud bumps 4 as an alternative to the use of a pre-bumped semiconductor die. The copper stud bumping may be performed at the wafer level or may be performed after a die attach process. As in the prior embodiments, the first conductive structure precursors 4-1 may be overmolded as shown by reference number 6-1.

As in previously described processes, a grinding process (or other material removal process) can be performed to expose the first conductive structures 4. Then, a plating process can be performed. The resulting package is shown in FIG. 17(b). This embodiment can be less expensive to produce than embodiments that use solder bumps as the first conductive structures.

FIG. 17(c) shows dual, stacked, copper bumps on a semiconductor die 3. FIG. 17(d) shows a top view and an option for a triangular arrangement of copper bumps to provide larger contact area to subsequently deposited solder bumps, thus establishing better solder joints. Copper stud groupings may also include more than three stud bumps. As shown, the first conductive structures 4 may be side-by-side in a single plane.

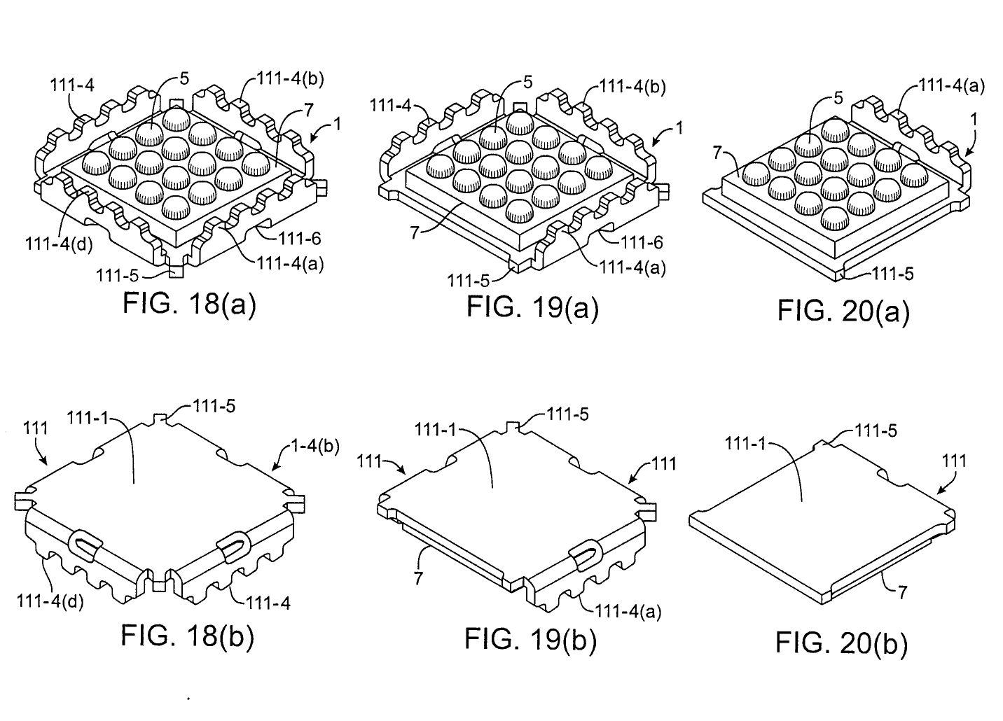

FIGS. 18(a)-18(b) show a semiconductor die package comprising a leadframe structure 111 including four leads 111-4(a), 111-4(b), 111-4(c), 111-4(d) with drain stud terminals. FIGS. 19(a)-19(b) show three leads in a leadframe structure 111, while FIGS. 20(a)-20(b) show one lead in a leadframe structure 111. Other features that are shown in clued a back surface 111-1 and tie bars 111-5.

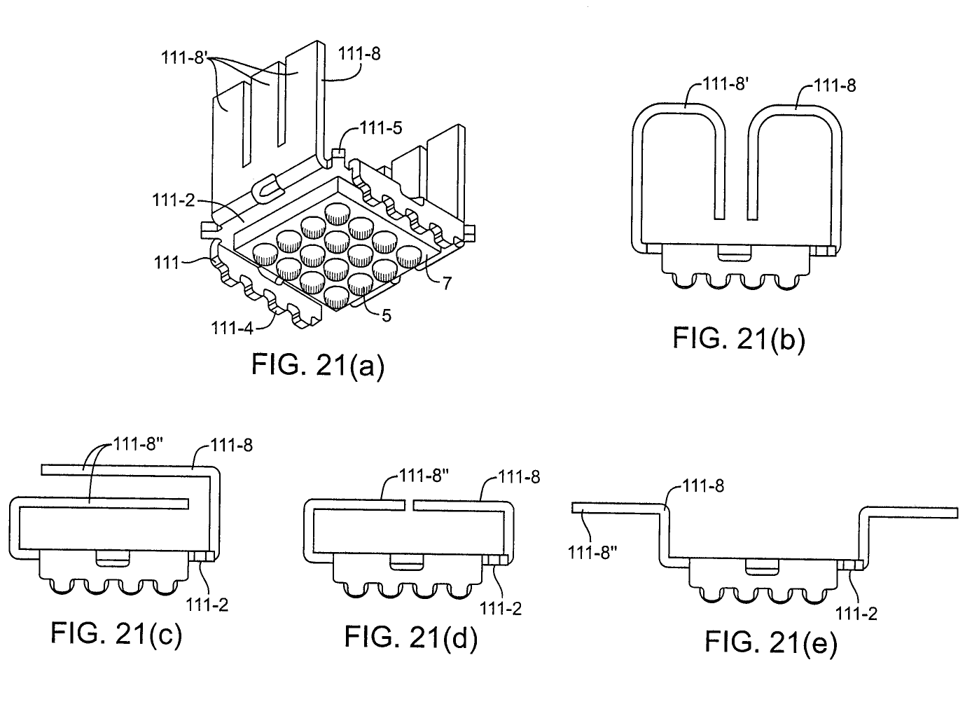

FIG. 21(a) shows perspective view of an embodiment including a leadframe structure with built-in heat sink structures. The heat sink structures 111-8 extend from a die attach pad 111-2 of a leadframe structure. FIGS. 21(b)-21(e) show various bending options for the laterally extended heat sink structures 111-8. The leadframe structures 111-8 laterally extend from the die attach pad 111-2, even though they can bent in some embodiments. Bending of the leadframe structure may occur before or after attachment to a semiconductor die.

FIG. 21(a) shows two heat sink structures 111-8 on opposite sides of the die attach pad 111-2 in the leadframe structure 111, and being perpendicularly oriented with respect to the die attach pad 111-2. Each heat sink structure 111-8 includes three heat sink structure portions 111-8′.

FIG. 21(b) shows the two heat sink structure sections 111-8″ forming U-shapes. Each section 111-8″ may include part of the previously described portions 111-8′. FIG. 21(c) shows the two heat sink structure structures 111-8 that are bent so that sections 111-8″ thereof are parallel with the die attach pad 111-2 of the leadframe structure 111 and overlap with the die attach pad 111-2. FIG. 21(d) shows the heat sink structures 111-8 bent so that sections 111-8″ thereof are coplanar and overlap and are parallel with the die attach pad 111-2. FIG. 21(e) shows the heat sink structures 111-8 with sections 111-8″ that extend laterally away from each other, and are parallel with respect to the die attach pad 111-2.

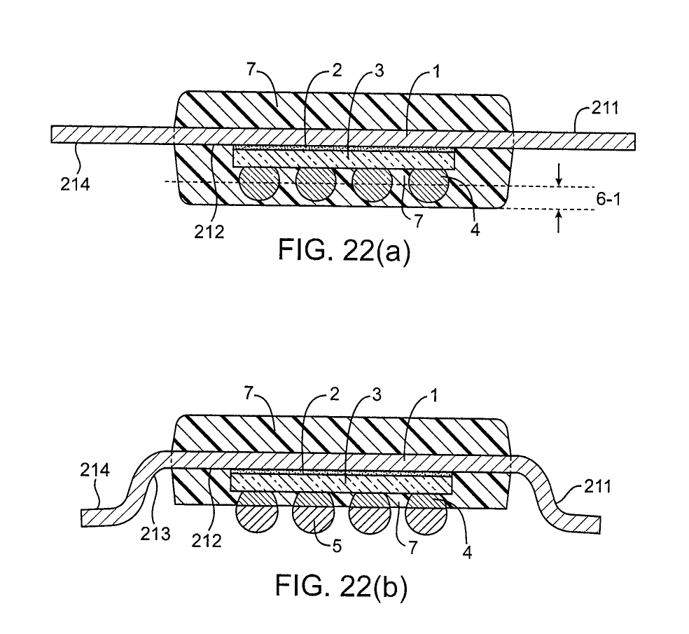

FIGS. 22(a)-22(b) shows an over molded bumped die, wherein the molding may be the same as the standard molding outline of an SOT, SOIC, TSSOP or like semiconductor die package. The materials may be the same as the material mentioned in FIG. 1. The leadframe structure 211 includes a die attach pad 212, and a bend 213 that defines leads 214 in FIG. 22(b). The first conductive structures 4 may be in the form of solder bumps, but may alternatively be in the form of copper stud bumps. This design option can undergo surface grinding or the removal of the area corresponding to reference number 6-1.

FIG. 22(b) is a section view of lead formed terminal 214. Second conductive structures 5 can be attached to the first conductive structures 4 as previously described. The leadframe structure 1 thickness and lead form outline terminal 214 may also vary to match the molded outline size that may apply to SOT, SOIC, TSSOP or like package designs. Terminal lead 214 may also be formed as a “C” or “J” shape, or could be a reverse lead form.

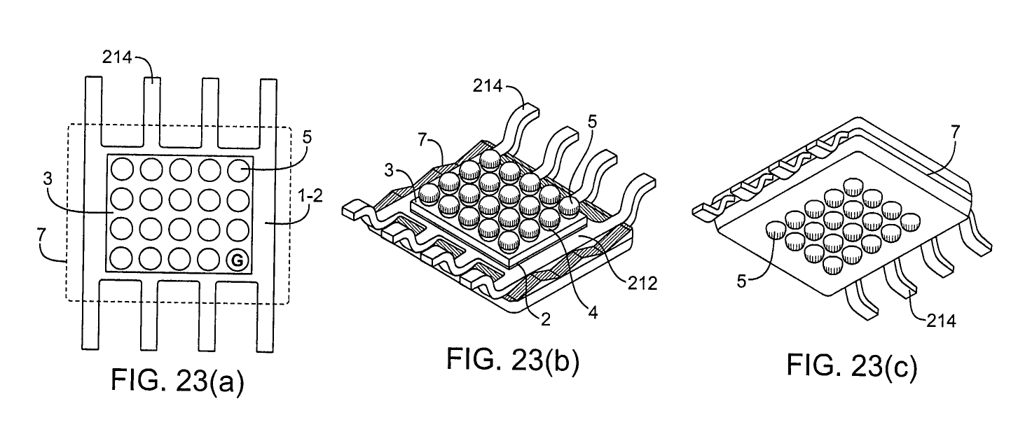

FIG. 23(a) is a top view of a single bumped semiconductor die 3 in a semiconductor die package. The semiconductor die package comprises a molded body 7 that is represented by a dashed line. A gate bump is marked with the letter “G”. The lead frame material may be bare copper or having fully plated or having a selective plating on the die attach pad 1-2 area.

FIG. 23(b) is an isometric view of the semiconductor die package with the mold compound 6 being partially removed.

FIG. 23(c) is a bottom perspective view showing the complete mold compound and the orientation of the second conductive structures 5 on the bottom side of the semiconductor die package.

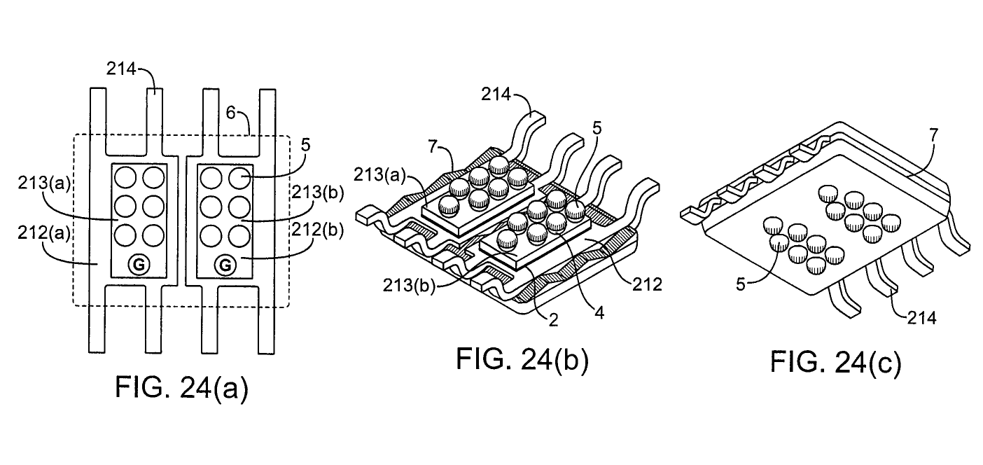

FIG. 24(a) shows a top view of dual bumped dies 213(a), 213(b), and a molded body 7 that is represented by dashed line. A gate location marked with “G” is on one of the bumps. The lead frame material may be bare copper, or may be fully or selectively plated or having fully plated (e.g., only on die attach pads 212(a), 212(b)).

FIG. 24(b) is a bottom perspective view of the semiconductor die package with a portion of the mold compound 7 being removed.

FIG. 24(c) is a bottom perspective view of the semiconductor die package. Second conductive structures 5 are on the bottom.

Any one or more features of one or more embodiments may be combined with one or more features of any other embodiment without departing from the scope of the invention.

Any recitation of “a”, “an” or “the” is intended to mean “one or more” unless specifically indicated to the contrary.

The above description is illustrative but not restrictive. Many variations of the invention will become apparent to those skilled in the art upon review of the disclosure. The scope of the invention should, therefore, be determined not with reference to the above description, but instead should be determined with reference to the pending claims along with their full scope or equivalents.

What is claimed is:

1. A semiconductor die package comprising:
a leadframe structure;
a semiconductor die coupled to the leadframe structure;
a plurality of first conductive structures attached to the semiconductor die;
a plurality of second conductive structures attached to the plurality of first conductive structures; and
a molding material, wherein the molding material covers at least portions of the plurality of first conductive structures, the leadframe structure, and the semiconductor die.

2. The semiconductor die package of claim 1 wherein molding material covers and contacts side surfaces of the plurality of first conductive structures, but does not cover end surfaces of the plurality of first conductive structures.

3. The semiconductor die package of claim 1 wherein the plurality of first conductive structures comprise a first solder material and the plurality of second conductive structures comprise a second solder material.

4. The semiconductor die package of claim 3 wherein the first solder material has a higher melting temperature than the second solder material.

5. The semiconductor die package of claim 1 wherein the semiconductor die comprises a vertical device.

6. The semiconductor die package of claim 1 wherein leadframe structure has a die attach pad and leads extending from the die attach pad, wherein the semiconductor die is attached to the die attach pad.

7. The semiconductor die package of claim 1 wherein the semiconductor die package further comprises a plurality of third conductive structures, the third conductive structures in the plurality of third conductive structures being attached to the leads of the leadframe structure.

8. The semiconductor die package of claim 7 wherein the molding material covers and contacts side surfaces of the plurality of first conductive structures, but does not cover end surfaces of the plurality of first conductive structures

9. The semiconductor die package of claim 1 wherein the semiconductor die comprises a vertical MOSFET.

10. A method for forming a semiconductor die package, the method comprising:
molding a molding material around at least a portion of a plurality of first conductive structure precursors, at least a portion of a semiconductor die, and at least a portion of a leadframe structure, wherein the semiconductor die is attached to the leadframe structure, and wherein the first conductive structure precursors in the plurality of first conductive structure precursors are attached to the semiconductor die;
removing portions of the first conductive structure precursors in the plurality of first conductive structure precursors and the molding material to form a plurality of first conductive structures; and
attaching a plurality of second conductive structures to the plurality of first conductive structures after molding.

11. The method of claim 10 wherein the molding material comprises a conductive epoxy material.

12. The method of claim 11 wherein removing portions of the plurality of first conductive structure precursors and the molding material comprises performing a surface grinding process.

13. The method of claim 10 further comprising plating surfaces of the leadframe structure after molding.

14. The method of claim 10 further comprising attaching a plurality of third conductive structures to leads in the leadframe structure.

15. The method of claim 10 wherein after removing, the molding material covers and contacts side surfaces of the plurality of first conductive structures, but does not cover end surfaces of the plurality of first conductive structures.

16. The method of claim 10 wherein the plurality of first conductive structures comprise a first solder material and the plurality of second conductive structures comprise a second solder material.

17. The method of claim 10 wherein the semiconductor die comprises a vertical device.

18. The method of claim 10 further comprising, after molding, removing part of the first conductive structure precursor and the molding material to form a planar surface, wherein the planar surface comprises coplanar surfaces of the first conductive structures and the molding material.

19. The method of claim 10 further comprising manipulating the leadframe structure, such that the leadframe structure includes a die attach pad and substantially perpendicular leads extending from the die attach pad.

20. The method of claim 10 wherein the leadframe structure comprises drain leads.

21. A semiconductor die package comprising:
a leadframe structure comprising a die attach pad and a plurality of extended heat sink structures;
a semiconductor die coupled to a leadframe structure;
a plurality of conductive structures attached to the semiconductor die; and
a molding material, wherein the molding material covers at least portions of the leadframe structure, and the semiconductor die,
wherein the heat sink structures extend away from the semiconductor die.

22. The semiconductor die package of claim 21 wherein the heat sink structures, the semiconductor die, and the die attach pad overlap.

23. The semiconductor die package of claim 21 wherein the heat sink structures extend laterally away from each other.

24. The semiconductor die package of claim 21 wherein the semiconductor die comprises a vertical MOSFET.

25. The semiconductor die package of claim 21 further comprising a conductive adhesive disposed between the semiconductor die and the leadframe structure.

26. A method for forming a semiconductor die package, the method comprising:
attaching a semiconductor die to a die attach pad of a leadframe structure, wherein the leadframe structure comprises the die attach pad and a plurality of extended heat sink structures; and
molding a molding material around at least portions of the leadframe structure, and the semiconductor die,
wherein the heat sink structures extend away from the semiconductor die in the formed package.

27. The method of claim 26 further comprising bending the heat sink structures after attaching the semiconductor die to the leadframe structure.

28. The method of claim 26 wherein the semiconductor die comprises a vertical device.

29. The method of claim 26 wherein the heat sink structures and the die attach pad lie within the same plane prior to and after molding.

30. The method of claim 26 wherein the heat sink structures and the die attach pad lie within the same plane prior to molding, and wherein the method further comprises:
bending the leadframe structure so that the heat sink structures lie in a different plane than the die attach pad, after molding.

31. The method of claim 26 wherein the semiconductor die comprises a power MOSFET.

32. The method of claim 26 further comprising attaching a first plurality of conductive structures to the semiconductor die and attaching a second plurality of conductive structures to the first plurality of conductive structures.

33. The method of claim 32 wherein the leadframe structure comprises copper.

34. The method of claim 32 wherein the leadframe structure comprises copper.
